(19) United States
(12) Patent Application Publication
(10) Pub. No.: US 2015/0255643 A1
(43) Pub. Date: Sep. 10, 2015

(54) ELECTRODE FORMING PASTE COMPOSITION, AND METHOD OF MANUFACTURING ELECTRODE AND SOLAR CELL EACH USING THE SAME

(71) Applicant: Tokyo Ohka Kogyo Co., Ltd., Kawasaki-shi (JP)

(72) Inventor: Masaru Abe, Kawasaki-shi (JP)

(21) Appl. No.: 14/641,642

(22) Filed: Mar. 9, 2015

(30) Foreign Application Priority Data
Mar. 10, 2014 (JP) 2014-046126

(51) Int. Cl. H01L 31/0224; H01L 31/18; H01L 31/028; C09D 5/24

(52) U.S. Cl. CPC H01L 31/022425; C09D 5/24; H01L 31/18; H01L 31/028

(57) ABSTRACT

An electrode forming paste composition (EFPC) which even when not fired at a high temperature at which a BSF layer is formed, is able to provide an electrode showing satisfactory adhesiveness to a silicon substrate and excellent electrical characteristics, a method of manufacturing an electrode using the EFPC, and a solar cell using the EFPC. The EFPC includes an aluminum-silicon alloy powder, an organic polymer, a silicon-containing polymer, and an adherence agent composed of an amine-based compound and/or an amide-based compound. The manufacturing method includes forming a composition layer including the EFPC on a silicon substrate; and firing the composition layer at a temperature of 577° C. or lower. The solar cell includes an electrode formed on a silicon substrate using the EFPC.

### CROSS-REFERENCE TO RELATED APPLICATIONS

This application claims priority to Japanese Patent Application No. 2014-046126, filed Mar. 10, 2014, the content of which is incorporated herein by reference.

### BACKGROUND OF THE INVENTION

1. Technical Field

The present invention relates to an electrode forming paste composition, a method of manufacturing an electrode using the electrode forming paste composition, and a solar cell using the electrode forming paste composition.

2. Description of Related Art

Solar cells include a silicon substrate having PN junction. In general, an n⁺ layer (n-type impurity layer) is formed on the front surface side (light-receiving surface side) of the silicon substrate, and an antireflection film and a front surface electrode are provided on this n⁺ layer. Meanwhile, a back surface electrode is provided on the back surface side of the silicon substrate. In a firing process thereof, a p⁺ layer (BSF (back surface field) layer) is formed. The BSF layer can be, for example, formed by firing an aluminum paste coated on a silicon substrate at a high temperature as 700° C. or the like and undergoing a eutectic reaction with the silicon substrate, thereby applying erosion and diffusion. By forming the BSF layer, adhesiveness between the silicon substrate and the back surface electrode becomes satisfactory, and electrical characteristics of a solar cell can be enhanced, and a warp of the silicon substrate can be suppressed. For example, Patent Literature 1 discloses an aluminum ink composition for making an electrode in a silicon solar cell including aluminum powders, a vehicle, an inorganic polymer, and a dispersant and a method of making a silicon solar cell including a step of printing the aluminum ink composition on a back of a silicon semiconductor substrate to form a BSF layer.

### DOCUMENT OF RELATED ART

### Patent Document

Patent Literature 1: JP-T-2012-508812

### SUMMARY OF THE INVENTION

However, there is encountered such a problem that the silicon substrate is apt to be damaged due to high-temperature firing at the time of forming the BSF layer or the reaction between the aluminum paste and the silicon substrate.

In view of the foregoing problem, the present invention has been made, and an object of the present invention is to provide an electrode forming paste composition which even when not fired at a high temperature at which a BSF layer is formed, is able to provide an electrode showing satisfactory adhesiveness to a silicon substrate and excellent electrical characteristics, a method of manufacturing an electrode using the electrode forming paste composition, and a solar cell using the electrode forming paste composition.

The present inventor has found that by using an aluminum-silicon alloy powder as a conductive material in an electrode forming paste composition and adding an adherence agent composed of an amine-based compound and/or an amide-based compound to this electrode forming paste composition, the foregoing problem can be solved, leading to accomplishment of the present invention.

A first aspect of the present invention is concerned with an electrode forming paste composition for forming an electrode on a silicon substrate, including an aluminum-silicon alloy powder, an organic polymer, a silicon-containing polymer, and an adherence agent composed of an amine-based compound and/or an amide-based compound.

A second aspect of the present invention is concerned with a method of manufacturing an electrode, including a composition layer forming step of forming a composition layer composed of the foregoing electrode forming paste composition on a silicon substrate; and a firing step of firing the composition layer at a temperature of 577° C. or lower.

A third aspect of the present invention is concerned with a solar cell including an electrode formed on a silicon substrate using the foregoing electrode forming paste composition.

According to the present invention, it is possible to provide an electrode forming paste composition which even when not fired at a high temperature at which a BSF layer is formed, is able to provide an electrode showing satisfactory adhesiveness to a silicon substrate and excellent electrical characteristics, a method of manufacturing an electrode using the electrode forming paste composition, and a solar cell using the electrode forming paste composition. The electrode forming paste composition according to the present invention provides an electrode showing satisfactory adhesiveness to a silicon substrate and excellent electrical characteristics through firing at 577° C. or lower, namely at a eutectic temperature between aluminum and silicon or lower. Since it is not needed to perform the firing at a temperature exceeding the eutectic temperature, a reaction between aluminum in the aluminum-silicon alloy powder and the silicon substrate is not caused, and the silicon substrate is hardly damaged.

### DETAILED DESCRIPTION OF THE INVENTION

### <Electrode Forming Paste Composition>

The electrode forming paste composition according to the present invention is a composition for forming an electrode on a silicon substrate and includes an aluminum-silicon alloy powder, an organic polymer, a silicon-containing polymer, and an adherence agent composed of an amine-based compound and/or an amide-based compound. By using the electrode forming paste composition according to the present invention, it is possible to form an electrode showing satisfactory adhesiveness to the silicon substrate and excellent electrical characteristics on the silicon substrate.

### [Aluminum-Silicon Alloy Powder]

In the electrode forming paste composition according to the present invention, the aluminum-silicon alloy powder is used as a conductive material. The aluminum-silicon alloy powder may be used solely or in combination of two or more kinds thereof.

The larger an average particle diameter of the aluminum-silicon alloy powder, the slower a sintering rate is. Accordingly, the average particle diameter of the aluminum-silicon alloy powder may be arbitrarily set up taking into consideration a desired sintering rate and any influence to be given in a step of forming an electrode. The average particle diameter of the aluminum-silicon alloy powder is preferably 1 to 5 μm. It is to be noted that the average particle diameter as referred to in the present specification means a volume accumulated average particle diameter (D₅₀) as measured by means of the laser diffraction method.

A proportion of silicon in the aluminum-silicon alloy powder is not particularly limited, and it is preferably 5 to 25 atomic %, and more preferably 10 to 15 atomic %.

A content of the aluminum-silicon alloy powder is preferably 50 to 90 mass %, and more preferably 70 to 80 mass % relative to the whole mass of the electrode forming paste composition according to the present invention. When the content of the aluminum-silicon alloy powder falls within the foregoing range, it is easy to form a back surface electrode composed of a smooth and uniform film.

### [Organic Polymer]

The organic polymer acts as an organic binder of the aluminum-silicon alloy powder, and it not only gives satisfactory viscosity to the electrode forming paste composition according to the present invention but also gives adhesion of a composition layer to be formed in a composition layer forming step as described later to the silicon substrate. The organic polymer may be used solely or in combination of two or more kinds thereof.

Specific examples of the organic polymer include acrylic resins such as polymethyl methacrylate and a polymethacrylate of a lower alcohol; epoxy resins; phenol resins; melamine resins; urea resins; xylene resins; alkyd resins; unsaturated polyester resins; furan resins; urethane resins; polyethylene resins; polypropylene resins; polystyrene resins; polyvinyl acetate resins; polyvinyl alcohol resins; polyacetal resins; polycarbonate resins; polyethylene terephthalate resins; polybutylene terephthalate resins; polyphenylene oxide resins; polyarylate resins; polyetheretherketone resins; cellulose resins such as ethyl cellulose, nitrocellulose, and ethylhydroxyethyl cellulose; polyvinyl alcohol resins such as polyvinyl butyral; and rosin resins such as wood rosin. Above all, acrylic resins and cellulose resins are preferably used from the viewpoints of printability and coatability.

A content of the organic polymer is preferably 1 to 20 mass %, and more preferably 4 to 8 mass % relative to the whole mass of the electrode forming paste composition according to the present invention. When the content of the organic polymer falls within the foregoing range, the above-described effects to be brought due to the addition of the organic polymer are apt to be exhibited sufficiently.

### [Silicon-Containing Polymer]

The silicon-containing polymer is a component that substitutes a glass frit which has hitherto been used for electrodes of solar cells and the like, and it is used for allowing the metal to strongly adhere to the substrate at the time of sintering the aluminum-silicon alloy powder. The silicon-containing polymer may be used solely or in combination of two or more kinds thereof.

Examples of the silicon-containing polymer include polysiloxanes. Above all, a polysilsesquioxane is preferred, and polyphenylsilsesquioxane is more preferred. In the case where the silicon-containing polymer is a polymer having a terminal group, the terminal group is not particularly limited, and examples thereof include a hydroxyl group; and an alkyl group such as a methyl group and an ethyl group. Of these, a hydroxyl group is preferred from the viewpoint of electrical characteristics of the resulting electrode.

A content of the silicon-containing polymer is preferably 1 to 20 mass %, and more preferably 4 to 8 mass % relative to the whole mass of the electrode forming paste composition according to the present invention. When the content of the silicon-containing polymer falls within the foregoing range, the metal is apt to strongly adhere to the substrate at the time of sintering the aluminum-silicon alloy powder.

[Adherence Agent Composed of Amine-Based Compound and/or Amide-Based Compound]

The adherence agent composed of an amine-based compound and/or an amide-based compound acts as an adherence agent for the aluminum-silicon alloy powders each other and contributes to an enhancement of the electrical characteristics of the electrode which is formed from the electrode forming paste composition according to the present invention. Although details of the action due to the adherence agent are not always elucidated yet, it may be presumed that the adherence agent allows the aluminum-silicon alloy powders to crosslink with each other to form a complex, whereby the adherence action is promoted. The adherence agent may be used solely or in combination of two or more kinds thereof.

The amine-based compound is not particularly limited, and examples thereof include monoamine-based compounds having 3 to 15 carbon atoms, such as dodecylamine, tridecylamine, and 3-amino-1-propanol; and diamine-based compounds such as ethylenediamine, 2-hydroxyethylethylenediamine, 2-hydroxyethylpropylenediamine, dicyclohexylmethanediamine, and 2-hydroxyethylpropylenediamine, with diamine-based compounds being preferred. Above all, ethylenediamine, 2-hydroxyethylethylenediamine, 2-hydroxyethylpropylenediamine, and dicyclohexylmethanediamine are more preferred. In addition, the amide-based compound is not particularly limited, and examples thereof include ketoamide-based compounds such as N,N-dimethylacetamide, N,N-dimethylformamide, and N-methylpyrrolidone. Above all, dialkyl ketoamide-based compounds such as N,N-dimethylacetamide are more preferred.

A content of the adherence agent is preferably 0.1 to 10 mass %, and more preferably 1 to 5 mass % relative to the whole mass of the electrode forming paste composition according to the present invention. When the content of the adherence agent falls within the foregoing range, the electrical characteristics of the electrode which is formed from the electrode forming paste composition according to the present invention are apt to be enhanced.

### [Carboxylic Acid]

The electrode forming paste composition according to the present invention may also contain a carboxylic acid. The carboxylic acid acts as a fluxing agent. The carboxylic acid removes an oxide film from the metal surface such as the aluminum-silicon alloy powder surface and the silicon substrate surface to decrease electrical resistance on such a metal surface, thereby contributing to an enhancement of the electrical characteristics of the electrode which is formed from the electrode forming paste composition according to the present invention. The carboxylic acid may be used solely or in combination of two or more kinds thereof.

The carboxylic acid is not particularly limited, and it may be either a monovalent carboxylic acid or a polyvalent carboxylic acid such as a divalent carboxylic acid and a trivalent carboxylic acid. The carboxylic acid is preferably a polyvalent carboxylic acid, and more preferably a divalent carboxylic acid. Examples of the monovalent carboxylic acid include glycolic acid. Examples of the divalent carboxylic acid include malic acid and adipic acid. Examples of the trivalent carboxylic acid include citric acid.

A content of the carboxylic acid is preferably 0.1 to 10 mass %, and more preferably 1 to 5 mass % relative to the whole mass of the electrode forming paste composition according to the present invention. When the content of the carboxylic acid falls within the foregoing range, the above-described effects to be brought due to the addition of the carboxylic acid are apt to be exhibited sufficiently.

### [Organic Solvent]

The electrode forming paste composition according to the present invention may also contain an appropriate organic solvent such that it becomes a paste having physical properties suited for the composition layer forming step. The organic solvent may be used solely or in combination of two or more kinds thereof.

Specific examples of the organic solvent include cyclic ether-based compounds such as tetrahydrofuran, furan, tetrahydropyran, pyran, dioxane, 1,3-dioxolane, and trioxane; dialkyl sulfoxide-based compounds such as dimethyl sulfoxide and diethyl sulfoxide; ketone-based compounds such as acetone, methyl ethyl ketone, and diethyl ketone; alcohol-based compounds such as ethanol, 2-propanol, 1-butanol, and terpineol; chlorinated hydrocarbon-based compounds such as dichloroethylene, dichloroethane, and dichlorobenzene; ester-based compounds of polyhydric alcohols, such as 2,2,4-trimethyl-1,3-pentanediol monoacetate, 2,2,4-trimethyl-1,3-pentanediol monopropiolate, 2,2,4-trimethyl-1,3-pentanediol monobutyrate, 2,2,4-trimethyl-1,3-pentanediol monoisobutyrate, and 2,2,4-triethyl-1,3-pentanediol monoacetate; terpene-based compounds such as α-terpinene, myrcene, alloocimene, limonene, dipentene, α-pinene, β-pinene, terpineol, carvone, ocimene, and phellandrene; and mixtures of at least two or more kinds thereof.

A content of the organic solvent is preferably 1 to 20 mass %, and more preferably 5 to 15 mass % relative to the whole mass of the electrode forming paste composition according to the present invention. When the content of the organic solvent falls with the foregoing range, the electrode forming paste composition according to the present invention is apt to become a paste having physical properties suited for the composition layer forming step.

### [Other Components]

The electrode forming paste composition according to the present invention may contain various additives as other components. Examples of the various additives include a dispersant, a dispersion stabilizer, an antioxidant, a corrosion inhibitor, a defoaming agent, a plasticizer, a tackifier, a coupling agent, an electrostaticity imparting agent, a polymerization inhibitor, and a viscosity controlling agent. It is to be noted that the dispersant is preferably a carboxyl group-containing polymer-based dispersant from the standpoint of excellent dispersibility of the aluminum-silicon alloy powder. Examples thereof include FLOWLEN G-700 that is a carboxyl group-containing polymer modified product.

### [Manufacturing Method of Electrode Forming Paste Composition]

The electrode forming paste composition according to the present invention can be, for example, manufactured by mixing the above-described components by using a conventionally known mixer such as a planetary centrifugal mixer, in such a manner that the composition becomes a paste having physical properties suited for the composition layer forming step.

### <Manufacturing Method of Electrode>

The manufacturing method of an electrode according to the present invention includes a composition layer forming step of forming a composition layer composed of the electrode forming paste composition according to the present invention on a silicon substrate; and a firing step of firing the composition layer at a temperature of 577° C. or lower. In the firing step, the firing is performed at a temperature of 577° C. or lower, and therefore, a reaction between aluminum in the aluminum-silicon alloy powder and the silicon substrate is not caused, and the silicon substrate is hardly damaged. In the manufacturing method of an electrode according to the present invention, nevertheless the firing is performed at a low temperature as 577° C. or lower, an electrode showing satisfactory adhesiveness to the silicon substrate and excellent electrical characteristics may be obtained. The composition layer forming step and the firing step are hereunder described.

### [Composition Layer Forming Step]

In the composition layer forming step, a composition layer composed of the electrode forming paste composition according to the present invention is formed on a silicon substrate. Specifically, the composition layer can be, for example, formed by coating the electrode forming paste composition on a silicon substrate, followed by drying. On that occasion, the composition layer can be formed in a pattern form. The shape of the pattern is not particularly limited, and examples thereof include a parallel line form and a lattice form. As a coating method of the electrode forming paste composition, a conventionally known method which is adopted in the manufacture of a solar cell, such as screen printing, may be adopted. The electrode forming paste composition is coated and then dried using a conventionally known drying machine such as an electric drying machine. The composition layer formed in the composition layer forming step is fired by the subsequent firing step, thereby forming a back surface electrode.

### [Firing Step]

Subsequently, in the firing step, the composition layer is fired at a temperature of 577° C. or lower. When the firing temperature is 577° C. or lower, such is preferred from the standpoints that a reaction between the aluminum-silicon alloy powder and the silicon substrate is not advanced; and that the silicon substrate is hardly damaged. For the firing, for example, an electric furnace or the like is used. The firing may be performed in an inert gas atmosphere or may be performed in an air atmosphere. The firing may be performed under atmospheric pressure or may be performed under reduced pressure. The firing temperature is preferably 560° C. to 577° C. The composition layer is converted into an aluminum-silicon layer that is a fired body by the firing. In the case where the composition layer is formed in a pattern form, a conductive electrode pattern may be formed by the firing.

### <Solar Cell>

The solar cell according to the present invention includes an electrode formed on a silicon substrate using the electrode forming paste composition according to the present invention. In the solar cell according to the present invention, though the manufacturing method of an electrode is not particularly limited, it is preferably the manufacturing method of an electrode according to the present invention. The solar cell according to the present invention includes an electrode showing satisfactory adhesiveness to the silicon substrate and excellent electrical characteristics and is apt to have high efficiency.

### EXAMPLES

The present invention is hereunder described more specifically by reference to Examples, but it should be construed that the scope of the present invention is not limited by these Examples.

### Preparation of Paste Composition

### Comparative Example 1 and Examples 1 to 7

An aluminum-silicon alloy powder, an organic polymer, a silicon-containing polymer, an adherence agent, a carboxylic acid, a dispersant, and an organic solvent as shown in Table 1 were mixed using a planetary centrifugal mixer (“THINKY MIXER”, manufactured by Thinky Corporation), thereby obtaining a paste composition. It is to be noted that the use amount of each of the components is shown in Table 1 (unit: mass %). In addition, details of the aluminum-silicon alloy powder, the organic polymer, the silicon-containing polymer, the dispersant, and the organic solvent are as follows.

Aluminum-Silicon Alloy Powder

Al—Si (Si: 12 atomic %, Al: balance, average particle diameter: 1 to 3 μm)

Organic Polymer

Acrylic resin represented by the following formula (P1) (in the following formula (P1), l/m=70/30 (molar ratio))

Silicon-Containing Polymer

Polyphenylsilsesquioxane represented by the following formula (P2) (number average molecular weight: 850; in the following formula (P2), n is the number at which the number average molecular weight of the polyphenylsilsesquioxane represented by the following formula (P2) is 850)

Dispersant

Carboxyl group-containing polymer modified product: FLOWLEN G-700 (a trade name, manufactured by Kyoeisha Chemical Co., Ltd.)

Organic Solvent

(S1): Tripropylene glycol monomethyl ether

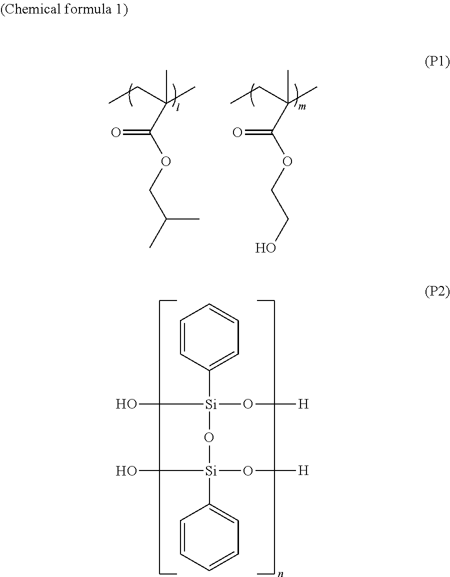

### <Measurement of Adhesion Strength>

Each of the compositions of the Examples and Comparative Example was coated in a pattern form on a silicon nitride substrate that is an insulator by means of screen printing. A composition layer formed in a pattern form was fired at 577° C. for 10 minutes in an air atmosphere at atmospheric pressure or in an air atmosphere under reduced pressure, thereby forming a conductive electrode pattern (30 mm×30 mm) made of an aluminum-silicon layer (film thickness: 10 μm) obtained as a fired body.

After laminating a nickel layer (film thickness: 5 μm) on the resulting pattern by means of plating, an epoxy adhesive-provided stud pin was installed perpendicularly to the nickel layer and heated and dried at 150° C. for 60 minutes, thereby immobilizing the stud pin. The stud pin was stretched perpendicularly to the conductive electrode pattern at a rate of 0.5 mm/min by using a Shimadzu compact table-top universal tester EZ test (a trade name, manufactured by Shimadzu Corporation), and an adhesion strength was measured as a tensile strength. Results are shown in Table 1.

### <Measurement of Sheet Resistance>

A conductive electrode pattern (30 mm×30 mm) made of an aluminum-silicon layer (film thickness: 10 μm) obtained as a fired body was formed in the same manner as that in the case of the above-described “Measurement of adhesion strength”.

A sheet resistance of the resulting conductive electrode pattern was measured by the four-point probe method using a sheet resistance measuring instrument (VR-70, manufactured by Kokusai Denki Kabushiki Kaisha). Results are shown in Table 1.

### <Measurement of Contact Resistance>

Each of the compositions of the Examples and Comparative Example was coated in a pattern form on a silicon substrate by means of screen printing. A composition layer formed in a pattern form was fired at 577° C. for 10 minutes in an air atmosphere at atmospheric pressure or in an air atmosphere under reduced pressure, thereby forming a conductive electrode pattern (line-and-space pattern, line width: 1 mm, pitch: 200 to 1,000 μm) made of an aluminum-silicon layer (film thickness: 10 μm) obtained as a fired body.

A contact resistance between the lines adjacent to each other in the resulting conductive electrode pattern was measured by the TLM method. Results are shown in Table 1.

TABLE 1

| | | Comparative | | | | | | | |
|---|---|---|---|---|---|---|---|---|---|
| | | Example | Example | | | | | | |
| | | 1 | 1 | 2 | 3 | 4 | 5 | 6 | 7 |
| Aluminum-silicon alloy | Al—Si | 76.0 | 76.0 | 76.0 | 76.0 | 76.0 | 73.0 | 73.0 | 73.0 |
| powder | | | | | | | | | |
| Organic polymer | Acrylic resin (P1) | 4.6 | 4.6 | 4.6 | 4.6 | 4.6 | 4.4 | 4.4 | 4.4 |
| Silicon-containing | Polyphenylsilsesquioxane | 6.0 | 6.0 | 6.0 | 6.0 | 6.0 | 5.8 | 5.8 | 5.8 |
| polymer | (P2) | | | | | | | | |
| Adherence agent | Ethylenediamine | | 3.6 | | | | | | |
| | Dodecylamine | | | 3.6 | | | | | |
| | 3-Amino-1-propanol | | | | 3.6 | | | | |
| | N,N-Dimethylacetamide | | | | | 3.6 | 3.6 | 3.6 | 3.6 |
| Carboxylic acid | Malic acid | | | | | | 3.6 | | |
| | Citric acid | | | | | | | 3.6 | |
| | Adipic acid | | | | | | | | 3.6 |
| Dispersant | FLOWLEN G-700 | 0.1 | | | | | | | |
| Organic solvent | (S1) | 13.3 | 13.3 | 13.3 | 13.3 | 13.3 | 13.3 | 13.3 | 13.3 |
| Adhesion strength | N | 3.28 | 7.58 | 4.61 | 4.53 | 7.82 | 7.17 | 3.41 | 8.62 |
| Sheet resistance | Ω/sq | 0.88 | 1.08 | 0.61 | 0.14 | 0.10 | 1.71 | 0.74 | 0.16 |
| Contact resistance | mΩcm² | 222.92 | 153.54 | 253.44 | 192.23 | 30.27 | 82.42 | 222.77 | 20.98 |

As shown in Table 1, as compared with Comparative Example 1 in which the adherence agent was not added, in Examples 1 to 4 in which the adherence agent was added, the adhesion strength was enhanced, and the sheet resistance and the contact resistance were in the same levels or lowered. As compared with Example 4, in Examples 5 to 7 in which the carboxylic acid was further added, particularly in Example 7, an enhancement of the adhesion strength and a lowering of the contact resistance were conspicuous.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. An electrode forming paste composition for forming an electrode on a silicon substrate, comprising an aluminum-silicon alloy powder, an organic polymer, a silicon-containing polymer, and an adherence agent comprising an amine-based compound and/or an amide-based compound.

2. The electrode forming paste composition according to claim 1, wherein the amine-based compound is a diamine-based compound.

3. The electrode forming paste composition according to claim 1, further comprising a carboxylic acid.

4. The electrode forming paste composition according to claim 2, further comprising a carboxylic acid.

5. A method of manufacturing an electrode, comprising:
forming a composition layer comprising the electrode forming paste composition according to claim 1 on a silicon substrate; and
firing the composition layer at a temperature of 577° C. or lower.

6. A solar cell comprising an electrode formed on a silicon substrate using the electrode forming paste composition according to claim 1.
